(19) United States
(12) Patent Application Publication
(10) Pub. No.: US 2019/0337970 A1
(43) Pub. Date: Nov. 7, 2019

(54) PROCESS FOR PRODUCING NANOPARTICLES

(71) Applicants: BASF SE, Ludwigshafen am Rhein (DE); Ghent University, Gent (BE)

(72) Inventors: Maximilian HEMGESBERG, Leverkusen (DE); Carlos LIZANDARA, Ludwigshafen (DE); Jan BENNEWITZ, Ludwigshafen (DE); Armin MEYER, Ludwigshafen (DE); Stephan A. SCHUNK, Heidelberg (DE); Timo EMMERT, Philippsburg (DE); Isabel van DRIESSCHE, Gent (BE); Katrien DE KEUKELEERE, Gent (BE); Hannes RIJCKAERT, Gent (BE); Glen POLLEFEYT, Gent (BE); Jonathan DE ROO, Gent (BE)

(73) Assignees: BASF SE, Ludwigshafen am Rhein (DE); Ghent University, Gent (BE)

(21) Appl. No.: 16/475,167

(22) PCT Filed: Jan. 9, 2018
(86) PCT No.: PCT/EP2018/050409

§ 371 Date: Jul. 1, 2019

(30) Foreign Application Priority Data
Jan. 11, 2017 (EP) 17150974.8

(51) Int. Cl. C07F 7/28; C09D 11/52; C09D 11/38; C09D 11/322; C09D 11/037

(52) U.S. Cl. CPC C07F 7/28; C09D 11/52; H01L 39/2483; C09D 11/322; C09D 11/037; C09D 11/38

(57) ABSTRACT

The present invention is in the field of processes for the production of nanoparticles. It relates to a process for the preparation of nanoparticles comprising heating a water-free solution containing (a) a metal-organic compound containing an alkaline earth metal and a group 4 metal, and (b) a stabilizer to at least 150° C. for at least 30 minutes.

The present invention is in the field of processes for the production of nanoparticles.

Nanoparticles have various applications, such as anti-corrosion layer, imaging agent, photoluminescent and photocatalytic material, catalyst, or pinning center for oxide superconductors. In most of these applications, it is advantageous to employ small crystalline nanoparticles. Processes for the production of nanoparticles are known from prior art.

De Roo et al. disclose in the Journal of the American Chemical Society volume 136 (2014) on pages 9650-9657 a process for the production of hafnium oxide nanocrystals starting from hafnium chloride. However, obtaining nanoparticles with more than one metal in a defined and reliable way remains difficult.

U.S. Pat. No. 6,329,058 discloses a process of preparing BaTiO₃ nanoparticles from an aqueous solution containing barium titanium alkoxide. However, colloidal stabilization, in particular in highly polar solvents, is challenging and thus not suitable for a reliable production process.

It was an object of the present invention to provide a process for the production of nanoparticles which can easily and reliably be stabilized. The nanoparticles should be highly uniform and crystalline. Also, it was aimed at a process of production of nanoparticles which are highly effective as pinning centers in superconductors.

These objects were achieved by a process for the preparation of nanoparticles comprising heating a water-free solution containing

(a) a metal-organic compound containing an alkaline earth metal and a group 4 metal, and

(b) a stabilizer

to at least 150° C. for at least 30 minutes.

Preferred embodiments of the present invention can be found in the description and the claims. Combinations of different embodiments fall within the scope of the present invention.

The term “nanoparticles” in the present context generally refers to particles with a mass average particle diameter of not more than 100 nm, preferably not more than 80 nm, in particular not more than 60 nm, such as not more than 40 nm. The mass average particle diameter is preferably measured by dynamic light scattering according to ISO 22412 (2008), preferably by using the Mie theory.

The process according to the present invention comprises heating a water-free solution. A solution in the context of the present invention is a mixture which is liquid at standard conditions, i.e. 25° C. and 1013 mbar. Any solid in the solution is molecularly dissolved which means that not more than 1 wt.-% of the solution constitutes solid particles of more than 1 nm diameter, preferably not more than 0.1 wt.-%, in particular not more than 0.01 wt.-%.

Water-free in the context of the present invention typically means that the solution has a water content of less than 500 ppm, preferably less than 200 ppm, in particular less than 100 ppm, such as less than 50 ppm. The term “ppm” refers to parts per million as commonly used. The water content of a solution can be determined by direct titration according to Karl Fischer, for example described in detail in DIN 51777-1 part 1 (1983).

According to the present invention the solution contains a metal-organic compound containing an alkaline earth metal and a group 4 metal. Alkaline earth metals include Be, Mg, Ca, Sr, Ba, preferably Sr or Ba, in particular Sr. Group 4 metals include Ti, Zr and Hf, preferably Ti. Preferably, the molar ratio of the alkaline earth metal and the group 4 metal in the metal-organic compound is 0.1 to 10, more preferably 0.2 to 5, in particular 0.5 to 2.

The metal-organic compound further contains one or more organic ligands. Preferably, the organic ligand is bound or coordinated to the alkaline earth metal and/or the group 4 metal in the metal-organic compound via an oxygen atom. Examples for such organic ligands include alcohofs, carboxylates, esters, ethers, aldehydes, ketones, preferably alcohols.

Alcohols include linear alkyl alcohols like methanol, ethanol, n-propanol, n-butanol, n-pentanol, n-hexanol, n-heptanol, n-octanol, n-nonanol, n-decanol, n-dodecanol, n-tetradecanol; branched alkyl alcohols like iso-propanol, sec-butanol, iso-butanol, tert-butanol, neo-pentanol, sec-hexanol, 2-ethylhexan-1-ol, 2-butyloctan-2-ol; alkenyl alcohols like palmitoleic alcohol, oleic alcohol, linoleic alcohol, arachidonic alcohol, retinol; aromatic alcohols like phenol, benzyl alcohol, p-cresol, 2-phenylethanol; oligoetheralcohols like 2-methoxyethanol, diethyleneglycol, methyl-diethyleneglycol, triethyleneglycol, methyl-triethyleneglycol, polyethyleneglycol with a molecular weight of 200 to 1000 g/mol, preferably 300 to 800 g/mol, in particular 400 to 600 g/mol, polypropyleneglycol with a molecular weight of 200 to 1000 g/mol, preferably 300 to 800 g/mol, in particular 400 to 600 g/mol. Alkyl alcohols and oligoetheralcohols are preferred, C₁ to C₁₂ alkyl alcohols are more preferred, in particular linear C₂ to C₁₀ alkyl alcohols. The alcohol in the metal-organic compound is preferably deprotonated at the oxygen atom to form an alcoholate.

Preferably, the metal-organic compound containing an alkaline earth metal and a group 4 metal is a compound of general formula (I) or general formula (II)

M¹(OR¹)₂M¹[M²(OR²)₅]₂ (I)

M¹(OR¹)₂M²(OR²)₄ (II)

wherein M¹ is an alkaline earth metal, M² is a group 4 metal, and R¹ and R² are alkyl, alkenyl, aryl or oligoether groups as described above for the residue of the alcohols. If R¹ and/or R² is an oligoether group, the metal-organic compound is usually a compound of general formula (II), otherwise it is usually a compound of general formula (I). For the particular case in which R¹ and R² are the same, general formula (II) becomes general formula (IIa)

M¹M²(OR¹)₆ (IIa)

According to the present invention, the solvent further contains a stabilizer. The stabilizer prevents aggregation of the nanoparticles which are formed in the process according to the present invention. A broad variety of stabilizers can be used, for example alcohols, thiols, carboxylic acids, amines, trialkylphosphine oxides. Preferably, an alcohol, a carboxylic acid, or a trialkyl phosphine oxide is employed as stabilizer. Preferred trialkyl phosphine oxides are trialkyl phosphine oxides with the same or different C₄ to C₂₀ alkyl groups, for example trioctyl phosphine oxide. Examples for carboxylic acids are stearic acid, palmitic acid, erucic acid, oleic acid, linoleic acid, linolenic acid, or lauric acid. C₆ to C₂₂ carboxylic acids are preferred, in particular oleic acid or lauric acid. Examples for alcohols include octanol, nonanol, decanol, dodecanol, tetradecanol, benzyl alcohol, phenoxyethanol, hydroxyethylbenzene. C₆ to C₂₂ alcohols are preferred, in particular benzyl alcohol.

In many cases, the metal-organic compound and the stabilizer form a solution under reaction conditions. If this is not the case, the solution preferably further contains a solvent. Solvents include polar and non-polar solvents, wherein a solvent is referred to as polar if it has a dipolar momentum of at least 1.65 D (Debye). Non-polar solvents include aliphatic hydrocarbons such as hexane, cyclohexane, iso-undecane, dodecane; aromatic hydrocarbons such as benzene, toluene, ethylbenzene, xylene, mesitylene; or halogenated solvents such as chloroform. Polar solvents include alcohols, esters, ethers, amides, amines. Alcohols are preferred, in particular C₁ to C₁₂ alcohols. Alcohols as described above are preferably used as solvent. Preferably, the alcohol contained in the metal-organic compound is also used as solvent in the solution.

The concentration of the metal-organic compound in the solution is preferably 1 to 1000 mmol/l, more preferably 5 to 500 mmol/l, in particular 20 to 200 mmol/l, such as 40 to 150 mmol/l. The concentration of the stabilizer in the solution is preferably 0.01 to 10 mol/l, more preferably 0.1 to 5 mol/l, in particular 0.5 to 2 mol/l.

According to the present invention, the solution is heated to at least 150° C., preferably to at least 200° C., in particular to at least 250° C. Usually, the temperature does not exceed 500° C. According to the present invention, the solution is heated for at least 30 minutes. This time refers to the time at the given temperature, i.e. excludes the time for heating up and cooling down. Preferably, the solution is heated for at least 1 hour, more preferably at least 2 hours, in particular at least 3 hours. Usually, the solution is not heated for longer than 12 hours.

Any method of heating is conceivable, for example by immersing the container containing the solution into a heat bath or by irradiating it, for example with microwave or infrared irradiation. Heating by microwave irradiation is preferred.

Usually, the nanoparticles precipitate after having heated the solution to at least 150° C. In this case, the nanoparticles are preferably separated from the liquid phase, preferably by centrifugation. Often is it useful to remove any remaining impurities by washing with a solvent, for example once or twice or three times. The nanoparticles obtained by the process of the present invention can easily be suspended in solvents by adding a stabilizer as described above.

The nanoparticles formed by the process according to the present invention are typically crystalline. Crystalline in the context of the present invention means that the degree of crystallinity of the particles is at least 50%, preferably at least 70%, in particular at least 90%. The degree of crystallinity is defined as the ratio of the mass average radius of the particles visually observed in the HR-TEM and the radius of the particles determined by evaluation of the full width at half maximum (FWHM) of the dominant peak of the X-ray diffraction pattern (XRD) using the DebyeScherrer equation. A ratio of 1 determines a degree of crystallinity of 100%. The nanoparticles typically have a mass average particle size of 2 to 50 nm. The nanoparticles can be purified by precipitation, for example by addition of acetone, removal of the solvent and resuspension.

The nanoparticles are particularly suitable as pinning centers in oxide superconductors. Preferably the superconductor contains REBa₂Cu₃O₇₋ₓ, wherein RE stands for rare earth or yttrium and x is 0.01 to 0.3, more preferably the superconductor contains YBa₂Cu₃O₇₋ₓ.

Preferably the superconductor is made by chemical solution deposition of an ink containing

(a) an yttrium or rare earth-containing compound,

(b) a alkaline earth metal-containing compound,

(c) a transition metal-containing compound,

(d) an alcohol, and

(e) the particles according to the invention.

The yttrium- or rare earth metal-containing compound, the alkaline earth metal-containing compound and the transition metal-containing compound include oxides, hydroxides, halogenides, carboxylates, alkoxylates, nitrates or sulfates. Carboxylates are preferred, in particular acetate or propionate. Carboxylates and alkoxylates can be substituted, preferably by fluorine, such as difluoroacetate, trifluoroacetate, or partially or fully fluorinated propionate.

At least one of the rare earth metal or yttrium containing compound, the alkaline earth metal containing compound and the transition metal containing compound contains fluorine. Preferably, the alkaline earth metal containing compound contains fluorine, for example as trifluoroacetate.

Preferably, the yttrium- or rare earth metal is yttrium, dysprosium, or erbium, in particular yttrium. Preferably, the alkaline earth metal is barium. Preferably, the transition metal is copper.

Preferably, the molar ratio of the transition metal-containing compound and yttrium or rare earth metal-containing compound in the ink is between 3:0.7 to 3:2, more preferably 3:1.2 to 3: 1.4. Preferably, the molar ratio of the transition metal-containing compound and the earth alkaline metal-containing compound in the ink is between 3:1 to 3:2, more preferably 3:1.7 to 3: 1.9.

The ink further contains an alcohol as described for the process above. Preferably, the alcohol is a mixture of methanol and C₂ to C₁₂ alcohols.

The ink contains the rare earth metal or yttrium containing compound, the alkaline earth metal containing compound and the transition metal containing compound in a molar ratio deemed optimal for the superconductor growth and/or properties, taking into consideration the molar composition of the respective metals in the superconductor to be produced. Their concentration thus depends on the superconductor to be produced. Generally, their concentration in the solution is independent of each other 0.01 to 10 mol/l, preferably 0.1 to 1 mol/l.

Preferably, the ink contains the nanoparticles at a concentration at which the molar ratio of the sum of all metals in the nanoparticles to the yttrium or rare earth-containing compound is 1 to 30%, more preferably 3 to 20%, in particular 5 to 15%. In many cases this corresponds to 0.1 to 5 weight % of nanoparticles with regard to the ink.

Preferably, the nanoparticles are additionally stabilized by an organic compound containing at least a phosphoric acid group and an ester group or at least two carboxylic acid groups. More preferably the nanoparticles are additionally stabilized by a compound of general formula (I)

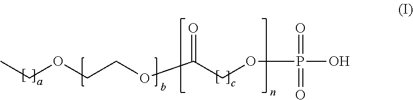

wherein a is 0 to 5, and

b and c are independent of each other 1 to 14, and

n is 1 to 5.

Preferably, a is 0. Preferably, b is 2 to 10, more preferably 3 to 8. Preferably, c is 2 to 10, more preferably 3 to 6. Preferably, n is 2 to 4. In one preferred example, a is 0, b is 6, c is 5, n is 3.

Also preferably, the organic compound containing at least a phosphoric acid group and an ester group or at least two carboxylic acid groups is a compound of general formula (II)

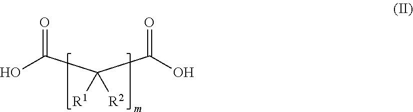

wherein R¹ and R² are independent of each other H, OH, or COOH, and

m is 1 to 12.

If m is larger than one, it is possible that the R¹ and R² are all the same or different to each other. Examples for the compound of general formula (II) include dicarboxylic acids in which R¹ and R² are hydrogen, such as malonic acid, succinic acid, glutaric acid, adipic acid, pimelic acid, azelaic acid, sebacic acid; dicarboxylic acids with hydroxyl groups such as tartronic acid, malic acid, tartric acid; or tricarboxylic acids such as citric acid or isocitric acid.

Another preferred organic compound containing at least a phosphoric acid group and an ester group or at least two carboxylic acid groups is a compound of general formula (III)

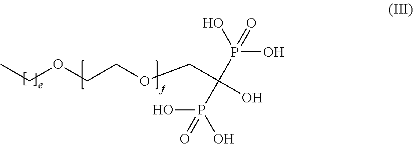

wherein e and f are independent of each other 0 to 12. Preferably e is 0. Preferably, f is 2 to 6.

Another preferred organic compound containing at least a phosphoric acid group and an ester group or at least two carboxylic acid groups is a compound of general formula (IV)

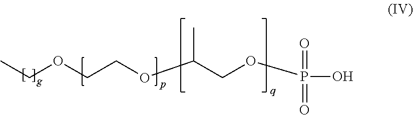

wherein g is 0 to 5, and

p and q are independent of each other 1 to 14, preferably 2 to 12. The ratio of p to q is preferably from 20:80 to 80:20, in particular from 40:60 to 60:40.

The organic compound containing at least a phosphoric acid group and an ester group or at least two carboxylic acid groups is brought in contact to the nanoparticles either by precipitating the nanoparticles from a suspension by a highly polar solvent such as acetone, separate the precipitate and redisperse the precipitate in an alcohol with the organic compound containing at least a phosphoric acid group and an ester group or at least two carboxylic acid groups. Alternatively, the organic compound containing at least a phosphoric acid group and an ester group or at least two carboxylic acid groups is added to a suspension of the nanoparticles, a high boiling alcohol is added and the lower-boiling solvent is removed by evaporation.

Preferably the ink further contains stabilizers, wetting agents and/or other additives. The amount of these components may vary in the range of 0 up to 30 weight % relating to the total weight of the dry compounds used. Additives might be needed for adjusting the viscosity. Additives include Lewis bases; amines such as TEA (triethanolamine), DEA (diethanolamine); surfactant; polycarboxylic acids such as PMAA (polymetacrylic acid) and PAA (polyacrylic acid), PVP (polyvinylpyrolidone), ethylcellulose.

Preferably the ink is heated and/or stirred to homogenize all ingredients, such as to reflux. In addition, the ink can further contain various additives to increase the stability of the solution and facilitate the deposition process. Examples for such additives include wetting agents, gelling agents, and antioxidants.

In order to make a superconductor with the ink according to the present invention, the ink is usually deposited on a substrate. The deposition of the ink can be carried out in various ways. The ink can be applied for example by dip-coating (dipping of the substrate in the ink), spincoating (applying the ink to a rotating substrate), spray-coating (spraying or atomizing the ink on the substrate), capillary coating (applying the ink via a capillary), slot die coating (applying the ink through a narrow slit), and ink-jet printing. Slot die coating and ink-jet printing are preferred.

Preferably, the ink is evaporated after deposition to form a film at a temperature below the boiling point of the solvent, such as 10 to 100° C. below the boiling point of the solvent, preferably 20 to 50° C. below the boiling point of the solvent.

The substrate may be any material capable of supporting buffer and/or superconducting layers. For example suitable substrates are disclosed in EP 830 218, EP 1 208 244, EP 1 198 846, EP 2 137 330. Often, the substrate is a metal and/or alloy strip/tape, whereby the metal and/or alloy may be nickel, silver, copper, zinc, aluminum, iron, chromium, vanadium, palladium, molybdenum, tungsten and/or their alloys. Preferably the substrate is nickel based. More preferably, the substrate is nickel based and contains 1 to 10 at-%, in particular 3 to 9 at-%, tungsten. Laminated metal tapes, tapes coated with a second metal like galvanic coating or any other multimaterial tape with a suitable surface can also be used as substrate.

The substrate is preferably textured, i.e. it has a textured surface. The substrates are typically 20 to 200 μm thick, preferably 40 to 100 μm. The length is typically greater than 1 m, the width is typically between 1 cm and 1 m.

Preferably the substrate surface is planarized before the film comprising yttrium or a rare earth metal, an alkaline earth metal and a transition metal is deposited onto, for example by electropolishing. It is often advantageous to subject the thus planarized substrate to a thermal treatment. This thermal treatment includes heating the substrate to 600 to 1000° C. for 2 to 15 minutes, wherein the time refers to the time during which the substrate is at the maximum temperature. Preferably, the thermal treatment is done under reducing atmosphere such as a hydrogen-containing atmosphere. The planarization and/or thermal treatment may be repeated.

Preferably, the surface of the substrate has a roughness with rms according to DIN EN ISO 4287 and 4288 of less than 15 nm. The roughness refers to an area of 10×10 μm within the boundaries of a crystallite grain of the substrate surface, so that the grain boundaries of the metal substrate do not influence the specified roughness measurement.

Preferably, between the substrate and the film there are one or more buffer layers. The buffer layer can contain any material capable of supporting the superconductor layer. Examples of buffer layer materials include metals and metal oxides, such as silver, nickel, TbOₓ, GaOₓ, CeO₂, yttria-stabilized zirconia (YSZ), Y₂O₃, LaAlO₃, SrTiO₃, Gd₂O₃, LaNiO₃, LaCuO₃, SrRuO₃, NdGaO₃, NdAlO₃ and/or some nitrides as known to those skilled in the art. Preferred buffer layer materials are yttrium-stabilized zirconium oxide (YSZ); various zirconates, such as gadolinium zirconate, lanthanum zirconate; titanates, such as strontium titanate; and simple oxides, such as cerium oxide, or magnesium oxide. More preferably the buffer layer contains lanthanum zirconate, cerium oxide, yttrium oxide, gadolinium-doped cerium oxide and/or strontium titanate. Even more preferably the buffer layer contains lanthanum zirconate and/or cerium oxide.

To enhance the degree of texture transfer and the efficiency as diffusion barrier, multiple buffer layers each containing a different buffer material are between the substrate and the film. Preferably the substrate includes two or three buffer layers, for example a first buffer layer comprising lanthanum zirconate and a second buffer layer containing cerium oxide.

The film is preferable heated to a temperature of 300 to 600° C., preferably 350 to 450° C. to remove remaining organic parts of the precursors. The substrate is kept at this temperature for 1 to 30 min, preferably 5 to 15 min.

Afterwards, the film is preferably heated to a temperature of 700 to 900° C., preferably 750 to 850° C. in an atmosphere containing water and oxygen to crystallize the film. The partial pressure of water is 1 to 99.5% of the total pressure of the atmosphere, and the partial pressure of oxygen is 0.5 to 90% of the total pressure of the atmosphere, preferably 2 to 90%. Even more preferably, during the first stage of heating to 700 to 900° C. the partial pressure of water is 1 to 20% of the total pressure of the atmosphere, preferably 1.5 to 5%, and during the second stage of this heating the partial pressure of water is 90 to 99.5% of the total pressure, preferably 95 to 99%.

Often, the superconductor wire is cut into smaller bands and stabilized by coating with a conductive metal such as copper for example by electrodeposition.

### BRIEF DESCRIPTION OF THE FIGURES

FIG. 1 shows the X-Ray diffractogram (XRD) of the nanoparticles obtained in example 1.

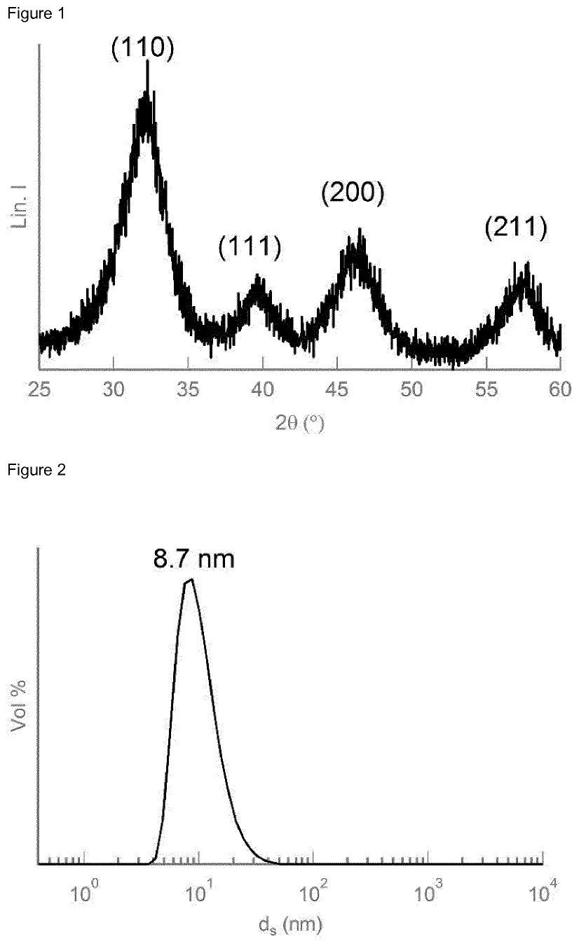

FIG. 2 shows the dynamic light scattering diagram of the particles obtained in example 1.

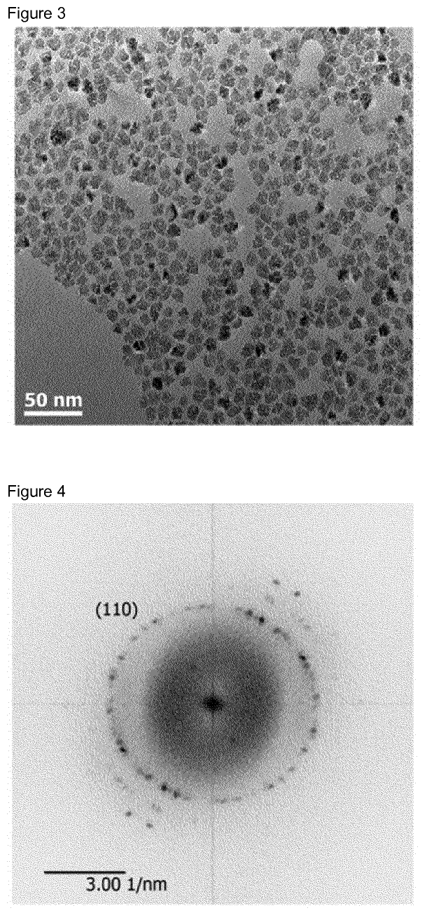

FIG. 3, 5-8 show the transmission electron microscopy images of the nanoparticles obtained in the examples 2-6.

FIG. 4 shows the XRD of the nanoparticles obtained in example 2.

FIG. 9 shows the X-Ray diffractogram (XRD) of the nanoparticles obtained in comparative example 2.

### EXAMPLES

### Example 1

Sr(MEE)₂Ti(MEE)₄, wherein MEE stand for (2-methoxyethoxy)ethoxide, was added to trioctylphosphine oxide (TOPO) at 100° C. to form a 0.2 M solution. The mixture was heated to 300° C. and left to react for 2 hours 20 minutes. The resulting mixture was dark orange. After precipitation in acetone twice, the precipitate was suspended in toluene to yield a turbid suspension which became immediately clear upon addition of some oleic acid.

### Example 2

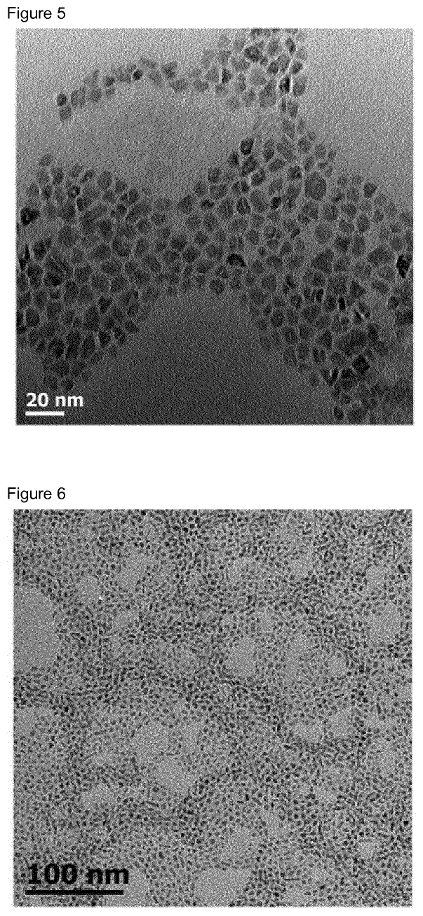

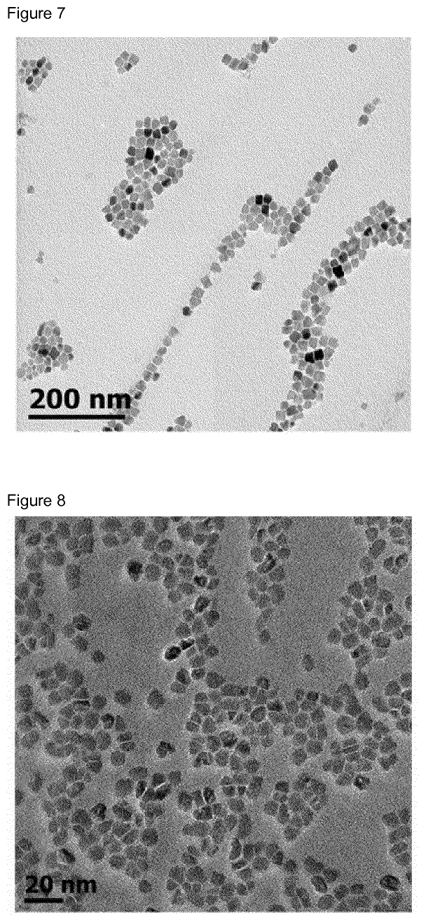

A 10 mL microwave vial was charged with 4 mL benzyl alcohol. Sr(MEE)₂Ti(MEE)₄ was added under vigorous stirring to obtain a clear, orangish solution with a concentration of 0.08 M. This vials was subjected to microwave heating for 4 hours using a 2.45 GHz Discover SP CEM Microwave at 270° C. A white precipitate and a supernatant formed. The precipitate was collected by centrifugation (4000 rpm, 3 min) and washed two times with ethanol and diethyl ether to remove excess of organic byproducts. 4 mL of toluene and 0.2 mmol oleic acid were added, whereupon a transparent suspension was obtained instantly. A transmission electron microscopy image of the obtained nanoparticles is shown in FIG. 3. A powder X-ray diffractogram is shown in FIG. 4.

### Example 3

The procedure according to example 2 was performed with Sr(ME)₂Ti(ME)₄, wherein ME stands for 2-methoxyethoxide. Upon suspension after the synthesis a transparent suspension was obtained instantly. A transmission electron microscopy image of the obtained nanoparticles is shown in FIG. 5.

### Example 4

The procedure according to example 2 was performed with Sr(Oct)₂Sr[Ti(Oct)₅]₂, wherein Oct stands for 1-octanolate. Upon suspension after the synthesis a transparent suspension was obtained instantly. A transmission electron microscopy image of the obtained nanoparticles is shown in FIG. 6.

### Example 5

The procedure according to example 2 was performed with Sr(OiPr)₂Sr[Ti(OiPr)₅]₂, wherein OiPr stands for isopropanolate. Upon suspension after the synthesis a transparent suspension was obtained instantly. A transmission electron microscopy image of the obtained nanoparticles is shown in FIG. 7.

### Example 6

The procedure according to example 2 was performed with Sr(OBn)₂Sr[Ti(OBn)₅]₂, wherein OBn stands for benzyl alcoholate. Upon suspension after the synthesis a transparent suspension was obtained instantly. A transmission electron microscopy image of the obtained nanoparticles is shown in FIG. 8.

Characterization of the Nanocrystals

The nanoparticles obtained in examples 1 to 6 were dried at 60° C. The dried samples were mixed with 10 wt-% ZnO (internal standard) and side loaded to a standard sample holder (8 mm height and 0.8 mm depth) to reduce preferential orientation effects. These samples were subject to X-Ray Diffraction (XRD) using a Thermo Scientific ARL X′tra X-ray diffractometer with the Cu K_{α} line as the primary X-ray source. The crystallite size was calculated via the Scherrer equation using 0.95 as shape factor. Rietveld quantitative analysis was selected to determine the crystallinity. TOPAS-Academic V4.1 software was used for performing Rietveld refinement. The results are summarized in the following table.

The solvodynamic diameter was determined via dynamic light scattering (DLS) using a Malvern Nano ZS in backscattering mode(173°) at a temperature of 25° C.

| | Crystal size | Crystallinity | Solvodynamic |
|---|---|---|---|
| Example | in nm | in % | diameter in nm |
| 1 | 3.5 | | 8.7 |
| 2 | 5.3 | 70 | 11.5 |
| 3 | 3.7 | 79 | 7.3 |
| 4 | 3.2 | 58 | 9.6 |
| 5 | 1.2 | 12 | |
| 6 | 6.5 | 45 | 13.8 |

### Comparative Example 1

Example 4 was performed with the difference that two moles of water with regard to the molar amount of the metal-organic compound were added. Complete resuspension was not possible.

### Comparative Example 2 (Corresponds to Example 4 of U.S. Pat. No. 6,329,058)

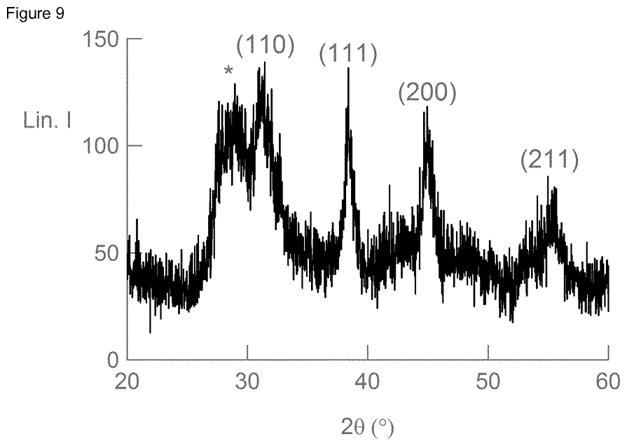

20 grams of the barium titanium ethoxide slurry was transferred into a 40 milliliter screw cap jar. The barium titanium ethoxide slurry was mixed with 0.73 gram hexanoic acid and 0.395 gram of deionized water. The mixture was shaken vigorously for approximately 1 minute and then transferred into an autoclave. The reactor head space was purged with dry nitrogen for 2 minutes. The autoclave was then heated to 225° C. for 2 hours. The slurry was collected and washed twice with acetone for XRD analysis. XRD analysis which is shown in FIG. 9 indicates the formation of cubic BaTiO₃, yet also an additional reflection is present at a 20 value of about 28° indicating the presence of rutile TiO₂. The crystallite size is about 10 nm. The crystallinity degree was determined using Rietveld refinement and indicated the presence of 16.8% crystalline cubic BaTiO₃.

The BaTiO₃ particles were stabilized in toluene as described in example 4 of U.S. Pat. No. 6,329,058 or methanol using stabilizer Ia, which is a compound of general formula (I) with a=0, b=6, c=5, n=2-3, or IIIa, which is a compound of general formula (III) with e=0 and f=5-6, directly after synthesis. Yet, from the DLS data it is clear that the stabilizer IIIa provides better stabilization in terms of solvodynamic diameter. Yet, all stabilization methods tend to show some agglomeration (higher Z-average and some tailing in the DLS data). The data are given in the following table.

| | | Z-average of the |
|---|---|---|
| | Solvodynamic | solvodynamic |
| | diameter in nm | diameter in nm |
| BaTiO₃ - oleic acid | 40 | 80 |
| BaTiO₃ - stabilizer Ia | 21 | 65 |
| BaTiO₃ - stabilizer IIIa | 8.1 | 66 |

1. A process for of preparing nanoparticles, the process comprising
heating a water-free solution containing
(a) a metal-organic compound containing an alkaline earth metal and a group 4 metal,
(b) a stabilizer, and
(c) a solvent
to a temperature of at least 150° C. for a period of at least 30 minutes.

2. The process according to claim 1, wherein the alkaline earth metal is Sr.

3. The process according to claim 1, wherein the group 4 metal is Ti.

4. The process according to claim 1, wherein the metal-organic compound contains an alcoholate.

5. The process according to claim 1, wherein the metal-organic compound contains a C₁ to C₁₀ alkyl alcoholate or an oligoether alcoholate.

6. The process according to claim 1, wherein a molar ratio of the alkaline earth metal and the group 4 metal in the metal-organic compound is 0.5 to 2.

7. The process according to claim 1, wherein the metal-organic compound is a compound of formula (I) or formula (II)
M¹(OR¹)₂M¹[M²(OR²)₅]₂ (I)
M¹M²(OR²)₆ (II)
where M¹ is an alkaline earth metal, M² is a group 4 metal, and R¹ and R² are each independently an alkyl, alkenyl, aryl or oligoether group.

8. The process according to claim 1, wherein the heating is performed via microwave irradiation.

9. The process according to claim 1, wherein the stabilizer is a C₆ to C₂₂ carboxylic acid.

10. The process according to claim 1, wherein the solvent is a C₁ to C₁₂ alcohol.

11. The process according to claim 1, wherein a concentration of the metal-organic compound in the solution is 10 to 200 mmol/l.

12. The process according to claim 1, wherein the nanoparticles are stabilized by an organic compound containing at least a phosphoric acid group and an ester group or at least two carboxylic acid groups.
